(19) United States
(12) Patent Application Publication
(10) Pub. No.: US 2012/0315582 A1
(43) Pub. Date: Dec. 13, 2012

(54) PATTERNED SUBSTRATE AND METHOD FOR PRODUCING SAME

(75) Inventors: Masaaki YOKOYAMA, Suita (JP); Norio NAGAYAMA, Suita (JP); Masato UEDA, Tsukuba (JP)

(73) Assignee: SUMITOMO CHEMICAL COMPANY, LIMITED, Tokyo (JP)

(21) Appl. No.: 13/593,612

(22) Filed: Aug. 24, 2012

Related U.S. Application Data
(62) Division of application No. 10/594,840, filed on May 20, 2008.

(30) Foreign Application Priority Data
Mar. 30, 2004 (JP) 2004-098502

(51) Int. Cl. G03F 7/20

(52) U.S. Cl. 430/311

(57) ABSTRACT

Disclosed is a patterned substrate having a conductor pattern. The conductor pattern is obtained by forming a layer (B) containing an organic polysilane on a conductive substrate (A), irradiating a certain region of the layer (B) with a radiation for oxidizing the organic polysilane constituting the layer (B) in the certain region, and then applying a solution containing a conducting polymer, water and/or a hydrophilic solvent over at least the certain region of the layer (B) for forming a layer (C) composed of the conducting polymer while impregnating the layer (B) in the certain region with the conducting polymer for electrically connecting the layer (C) and the substrate (A).

### CROSS-REFERENCE TO RELATED APPLICATIONS

This application is a Divisional of U.S. application Ser. No. 10/594,840, filed May 20, 2008; which is a 371 National Stage Application of PCT/JP05/06122, filed Mar. 30, 2005; which claims benefit of Japanese Application No. 2004-098502, filed Mar. 30, 2004; the entire disclosures of each of which are incorporated herein by reference.

### TECHNICAL FIELD

The present invention relates to a patterned substrate which has a conductor pattern made of a conducting polymer on a conductive substrate and to a method for producing the same.

### BACKGROUND ART

A patterned substrate, which has a conductor pattern made of a conducting polymer such as polythiophene or polyaniline on a conductive substrate, is useful as an electrode or the like used for an organic device etc.

Although there exists a patterned substrate which has been known to be produced by forming a conductor pattern composed of a conducting polymer layer on only a desired region on a conductive substrate through a printing method such as a flexographic printing method, a screen printing method, or an ink jet method by using a solution of conducting polymer, its accuracy is yet insufficient. For the purpose of solving such a problem, the present inventors have proposed a patterned substrate, which can be obtained by forming an organic polysilane layer on a conductive substrate, and irradiating a desired region with a radiation while dipping the organic polysilane layer into an electropolymerization solution, such that the organic polysilane on the region is allowed to be decomposed and eluted while a conducting polymer is precipitated on the region by electropolymerization in order to forming a conductive pattern (see Patent Document 1).

Patent Document 1: JP-A-7-249317

### DISCLOSURE OF THE INVENTION

### Problem to be Solved by the Invention

However, since this substrate is produced by employing electropolymerization, the production method is complicated and is not necessarily sufficient as an industrial process.

An object of the present invention is to provide a patterned substrate having a conductor pattern composed of a conducting polymer, the patterned substrate being able to be produced with a high degree of accuracy, conveniently, and with great productivity.

### Means for Solving the Problem

That is, the present invention provides a patterned substrate having a conductor pattern obtained by:

forming layer (B) comprising an organic polysilane on conductive substrate (A);

irradiating a certain region of the layer (B) with a radiation to oxidize the organic polysilane constituting the layer (B) in the certain region; and then

applying a solution containing a conducting polymer, water, and/or a hydrophilic solvent at least on the certain region of the layer (B) to form layer (C) comprising the conducting polymer, while impregnating the layer (B) in the certain region with the conducting polymer to electrically connect the layer (C) and the substrate (A).

### ADVANTAGES OF THE INVENTION

The patterned substrate according to the present invention can be produced with a high degree of accuracy, conveniently, and with great productivity.

### BRIEF DESCRIPTION OF THE DRAWINGS

FIG. 1 is a structural drawing of a device used for Reference Example 1 of the present invention;

FIG. 2 is an I-V characteristic diagram of the device used for Reference Example 1 of the present invention;

FIG. 3 is a structural drawing of a device used for Example 1;

FIG. 4 is a luminescence pattern of the device used for Example 1;

FIG. 5 is a luminescence intensity-voltage characteristic diagram of the device used for Example 1 of the present invention;

FIG. 6 is a structural drawing of a device used for Reference Example 2 of the present invention;

FIG. 7 is an I-V characteristic diagram of the device used for Reference Example 2 of the present invention;

FIG. 8 is a luminescence intensity-voltage characteristic diagram of a device used for Example 3 of the present invention; and

FIG. 9 shows luminescence pattern views of a device used for Example 4 of the present invention, in which a lower view shows a shadow mask pattern and an upper view shows a luminescence pattern.

### BEST MODE FOR CARRYING OUT THE INVENTION

A conductive substrate (A) used for the present invention is not particularly limited as long as the conductive substrate (A) is made of a material with conductivity which is sufficient for supplying electric charges to an organic device. Among the materials are, preferably, a metal plate or metal foil made of gold, platinum, copper, aluminum or the like, a glass substrate or plastic substrate on which a metal such as gold, platinum, or aluminum is deposited, and a glass substrate or plastic substrate on which a transparent electrode such as indium tin oxide (ITO), tin oxide (SnO₂), or zinc oxide (ZnO₂) is formed. Particularly, a glass substrate or plastic substrate on which ITO is formed, or alternatively a glass substrate or plastic substrate on which a metal such as gold, platinum, or aluminum is deposited is preferable.

In the present invention, a layer (B) composed of organic polysilane is firstly formed on the conductive substrate (A).

The organic polysilane used for the layer (B) is not restricted as long as it is a solvent-soluble organic polysilane of a known type or a derivative thereof such as described in a document (Chemical Review vol. 89, (1989) 1359). It is preferable to use organic polysilane which can be properly oxidized by irradiation, and among such materials are polydialkylsilane, polyalkylarylsilane, and polydiarylsilane, for example. Preferably an alkyl group includes 1 to 20 carbons and examples thereof are a methyl group, an ethyl group, a propyl group, a butyl group, a pentyl group, a hexyl group, and a cyclohexyl group, and among others the methyl group and the ethyl group are preferable. An aryl group preferably includes 6 to 60 carbons, and the aryl group may have a substituent group such as an alkyl group or an alkoxy group, and examples thereof are a phenyl group, a naphthyl group and the like, and among others the phenyl group is preferable. The organic polysilane may be a homopolymer composed of single repeating units or a copolymer composed of a plurality of repeating units.

Among examples of the organic polysilanes are polymethylphenylsilane, polyethylphenylsilane, polyethylnaphthylsilane, polymethylpropylsilane, polymethyl-t-butylsilane, polydiphenylsilane, polymethyltolylsilane, polymethylphenyl-co-ethylpropylsilane, and polymethylphenyl-co-diphenylsilane.

Although a molecular weight of the organic polysilane is not particularly limited as long as a homogeneous thin film can be obtained, generally the organic polysilane having a weight average molecular weight within a range from 1×10³ to 1×10⁷ is preferable, and the organic polysilane having a weight average molecular weight within a range from 1×10⁴ to 5×10⁶ is particularly preferable.

The layer (B) may further contain a compound which generates oxygen by irradiation (photoacid generator) as needed. As the photoacid generator, an agent which is publicly known as a component of a chemical sensitization resist can be used, and examples thereof are, as described in JP-A-05-23038, sulfonium salt, iodonium salt, a hydrobenzyl compound, a naphthoquinonediazide compound, onium salt, or a chlorinated organic compound for example.

Examples of a method for forming the above described layer (B) include spin coating, a casting method, a dipping method, a bar coat method, a roll coat method, an inkjet method, a screen printing method, a flexographic printing method and the like, which use a solution formed by dissolving the organic polysilane in an organic solvent. Preferably, the film is formed by applying a solution or a mixed solution through the spin coating method, the casting method, the dipping method, the bar coat method, the roll coat method, the inkjet method or the like.

Among the organic solvents in which the organic polysilane is dissolved are aromatic solvents such as benzene, toluene, and xylene, and ether-based solvents such as diethylether and tetrahydrofuran, and halogen-based solvents such as chloroform.

A film thickness of the above described layer (B) is not particularly limited as long as a certain film thickness suitable for a condition for irradiating the organic polysilane with a radiation and a condition for impregnating with the conducting polymer is selected in subsequent steps. For example, the film thickness of the layer (B) is preferably 5 nm to 1 μm, and is more preferably 20 to 200 nm.

When the film is formed by the coating method, the film thickness of the layer (B) varies depending on properties of the organic polysilane to be used, and can be adjusted by a concentration of the solution. For example, in the case of using polymethylphenylsilane whose molecular weight is on the order of 10⁴ as the organic polysilane, it is preferable to perform coating by the use of a solution formed by dissolving polymethylphenylsilane in toluene as the solvent to a concentration of 0.5 to 20 wt %.

Next, a certain region of the layer (B) is irradiated with a radiation to oxidize organic polysilane which constitutes the layer (B) of the region.

In this case, the radiation to be irradiated is not particularly limited as long as being an ultraviolet ray having a wavelength in the vicinity of a maximum absorption of the organic polysilane to be used and being an electron beam or an electromagnetic radiation having higher energy than the ultraviolet ray, such as an ultraviolet ray with a short wavelength or an X ray. An ultraviolet ray having a wavelength in the vicinity of the maximum absorption of the organic polysilane is most preferably.

Among methods for irradiating the predetermined region with the radiation are a method for irradiating through a shadow mask pattern and a method for scanning with a laser beam or an electron beam, however the method for irradiating through the shadow mask pattern is preferable in terms of productivity.

In addition, the radiation may be irradiated from a layer (B) side, and if the layer (A) is transparent or semi-transparent, the radiation may be irradiated from a layer (A) side, and it is preferable to irradiate from the layer (B) side. In addition, the radiation is preferably irradiated in a perpendicular direction to a surface of the layer (B).

Further, a dose of the radiation is determined by properties and film thickness of the organic polysilane, and thus the dose can not be uniquely decided, however, it is preferable that the dose is sufficient to oxidize the irradiated region throughout a direction of film thickness.

The above described irradiation of the radiation oxidizes the organic polysilane in the irradiated region and this region is made hydrophilic and, on the other hand, a portion which is not irradiated is remained in the organic polysilane. Therefore, if the layer (B) is irradiated through a shadow mask pattern, then only a portion corresponding to a shape of the pattern mask used, that is, a portion corresponding to a radiation transmitting part of the pattern mask is oxidized.

A condition of an area in the vicinity of the organic polysilane at the time of irradiating a radiation is not particularly limited as long as water molecules exist near a surface of the organic polysilane in terms of facilitating the oxidation of organic polysilane, and among such conditions is usually an atmosphere having a humidity of 30% or more. An atmosphere having a humidity of 50% or more is preferable, and an atmosphere having a humidity of 80% or more is more preferable. In addition, it is also preferable that the organic polysilane is irradiated while its surface is allowed to contact with water.

Thereafter, a solution containing a conducting polymer, water, and/or a hydrophilic solvent is applied at least on the certain region of the layer (B), which is irradiated with a radiation, in order to form a layer (C) comprising the conducting polymer, while the layer (B) in the certain region is impregnated with the conducting polymer to electrically connect the layer (C) and the substrate (A), and consequently a conductor pattern including the conducting polymer can be obtained.

The solution containing the conducting polymer, water, and/or the hydrophilic solvent herein also includes dispersions (hereinafter, sometimes referred to as “a conducting polymer solution”).

Although the conducting polymer works well by existing on the certain region of the layer (B) irradiated with a radiation, the conducting polymer may exist on a whole area of the layer (B) composed of the organic polysilane. It is preferable that the conducting polymer exists on the whole area in terms of productivity and flatness of a substrate surface.

Among such conducting polymers to be used are polythiophene and derivatives thereof, polyaniline and derivatives thereof, polypyrrole and derivatives thereof, polyacetylene and derivatives thereof, polyarylene and derivatives thereof, polyarylenevinylene and derivatives thereof, that is, it is preferable to use a conducting polymer which can be applied in a solution state and can form a thin film. In particular, polythiophene and derivatives thereof, and polyaniline and derivatives thereof are preferable, and polythiophene derivatives are more preferable, and poly(3,4-oxyethyleneoxythiophene) is more particularly preferable.

To control conductivities of the conducting polymer, it is preferable to include dopants therein. Among such dopants are preferably Lewis acids such as iodine, AsF₅, SbF₅, and HBF₄, inorganic acids such as perchloric acids, and organic acids such as sulfonic acid and polysulfonic acid, and the polysulfonic acid is particularly preferable. Although an amount to be added may be selected depending on its application, it is preferable that the amount is adjusted so as to be able to obtain a suitable conductivity because the too high conductivity leads to an increase in a leakage current between the irradiated parts.

To impregnate the irradiated region of the layer (B) with the conducting polymer, it is preferable that a surface of the irradiated region of the layer (B) is previously contacted with the conducting polymer solution. That is, the layer (B) is formed and this conductive substrate (A) irradiated with a radiation is dipped into the conducting polymer solution, or alternatively the layer (B) is formed and the conducting polymer solution is dropped on the conductive substrate (A) irradiated with a radiation for impregnating the irradiated region of the layer (B) with the conducting polymer in the solution. Subsequently a conducting polymer thin film is formed by a method as described below, and then water and/or the hydrophilic solvent are evaporated to form a conducting polymer having a predetermined film thickness on a surface of the layer (B).

In this case, it is preferable that a time during which the surface of the irradiated region of the layer (B) and the conducting polymer solution are contacted with each other and are kept as they are is 15 seconds or more. For example, in the case of spin coating, the conducting polymer solution is dropped on the substrate followed by keeping them for 15 seconds or more, and then the substrate is rotated at a predetermined revolution speed to form a conducting polymer thin film.

Examples of a coating method for forming the above described conducting polymer thin film include spin coating, a casting method, a dipping method, a bar coat method, a roll coat method, an inkjet method, a screen printing method, a flexographic printing method and the like, which use a conducting polymer solution. Among others, the spin coating method, the casting method, the dipping method, the bar coat method, the roll coat method, the inkjet method and the like are preferable.

Although the hydrophilic solvent is not particularly limited as long as being a liquid having a large interaction with water and having a high affinity for water, it is preferable to use a solvent having an atomic group including a polar group which exhibits an affinity for water such as a hydroxyl group, a carboxy group, an amino group, a carbonyl group, and a sulfo group, and among examples of such solvents are alcohols having 1 to 10 carbons such as methanol, ethanol, and isopropyl alcohol, glycols such as ethylene glycol and propylene glycol, and ketones such as acetone, and the solvent may be a mixture of 2 or more of the above described solvents or a mixture with water. A hydrophilic solvent containing 50% or more of alcohols or a mixture of this hydrophilic solvent and water is preferable.

A film thickness of the layer (C) is preferably 5 nm to 500 nm, and more preferably 20 to 200 nm.

The film thickness varies depending on properties of the conducting polymer to be used, and can be adjusted by a concentration of a coating liquid. A concentration of the coating liquid may be in a range of 0.1 wt % to 10 wt % and is preferably 0.5 wt % to 5 wt %, in terms of the conducting polymer solids.

Heat treatment is preferably performed after forming the layer (C), and for example, such heat treatment is performed in the air, in a nitrogen atmosphere, or in a vacuum. A temperature of the heat treatment depends on a type of conducting polymer, but is not particularly limited as long as being within a range in which the conducting polymer does not decompose nor degrade, and for example, a range from 50° C. to 250° C. is preferable and a range from 100° C. to 200° C. is more preferable. A time period for performing the heat treatment depends on a type of the conducting polymer and a temperature of the heat treatment, but is preferably within a range from 1 minute to 10 hours, and is more preferably within a range from 5 minutes to 2 hours, and is even more preferably within a range from 10 minutes to 1 hour.

Preferably, the organic polysilane constituting the layer (B) of a certain region is oxidized, followed by oxidizing a surface of the layer (B) excluding the certain region in order to make the surface hydrophilic. This lowers a conductivity on the surface of the organic polysilane thin film within a non-irradiated region, while making the surface of the organic polysilane thin film hydrophilic, so that an improvement of adhesion with the layer (B) is achieved when a conducting polymer layer (C) is formed in a next step.

Among such methods for oxidizing the surface is an ozone UV treatment, an oxygen plasma treatment, or an irradiation treatment in which a dose is restricted, however, the ozone UV treatment or the oxygen plasma treatment is preferable. This treatment requires only a moderate condition, since the organic polysilane thin film may be treated so that only the outermost surface thereof is oxidized and thus made hydrophilic.

It is also possible to oxidize the organic polysilane constituting the layer (B) of a certain region and then to impregnate the layer (B) of the region with the conducting polymer, followed by irradiating a radiation to oxidize the organic polysilane constituting the layer (B) excluding the certain region, in order for increasing an insulating property of the layer (B) excluding the certain region. As an irradiation method described above, it is possible to use a method for oxidizing the organic polysilane constituting the layer (B) of the above described region. The dose of the radiation depends on the type of the organic polysilane and the film thickness of the layer (B), but is sufficient if the organic polysilane constituting the layer (B) excluding the certain region can be oxidized which has a thickness required to decrease a current flowing through at least the remaining area excluding the certain region.

The method of production according to the present invention is a method for producing a patterned substrate having a conductor pattern, the method comprising: forming a layer (B) comprising an organic polysilane on a conductive substrate (A); irradiating a certain region of the layer (B) with a radiation to oxidize the organic polysilane constituting the layer (B) in the certain region; and applying a solution containing a conducting polymer, water, and/or a hydrophilic solvent at least on the certain region of the layer (B) to form a layer (C) comprising the conducting polymer, while impregnating the layer (B) in the certain region with the conducting polymer to electrically connect the layer (C) and the substrate (A) to produce the conductor pattern.

In addition, a patterned substrate according to the present invention is a substrate characterized by having, on a conductive substrate (A), a layer (B) comprising an irradiated region which contains an oxide of an organic polysilane produced by irradiating the organic polysilane with a radiation and a conducting polymer and a non-irradiated region which contains the organic polysilane, and having a layer (C) comprising the conducting polymer at least on the irradiated region of the layer (B), and for example this substrate can be produced by the above described production method.

An application of a patterned substrate according to the present invention will now be described.

The patterned substrate according to the present invention can be used for an organic electroluminescence device, an organic transistor device, an organic photo-sensor, or an organic solar cell as described in a document (Semiconducting Polymers: Eds. G. Hadziioannou and P. F. van Hutten (2000) WIELEY-VCH), and for an optical-optical conversion device or the like as described in a document (“Applied Physics” Vol. 64 (1995), 1036) for example.

The organic electroluminescence device can be fabricated by using the patterned substrate according to the present invention as an anode, on which a luminescent layer and cathode electrode are formed.

The organic transistor device can be fabricated by using the patterned substrate according to the present invention as a gate electrode, on which a gate dielectric film, an organic semiconductor film, a source electrode, and a drain electrode are formed, or alternatively using the patterned substrate according to the present invention as a source electrode and a drain electrode, on which an organic semiconductor film, a gate dielectric film, and a gate electrode are formed.

An organic photo-sensor or organic solar cell can be fabricated by using the patterned substrate according to the present invention as an electrode, on which a photoconductive organic thin film and a counter electrode are formed.

The optical-optical conversion device can be fabricated by combining the above described organic electroluminescent device with the organic photo-sensor on the patterned substrate according to the present invention.

### EXAMPLES Although the present invention will now be described in detail with reference to examples, the present invention should not be limited by the examples described below.

### Reference Example 1

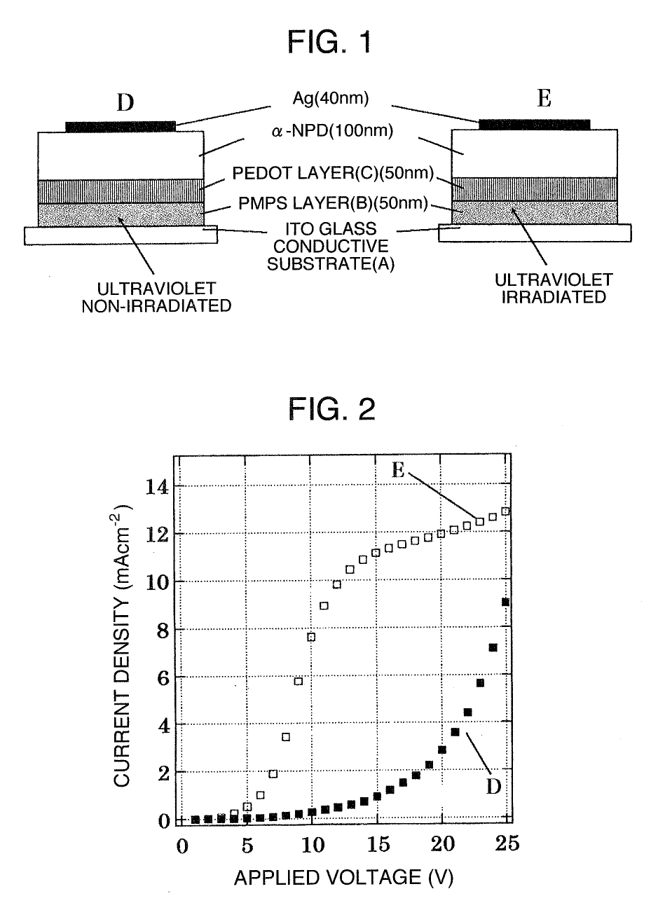

On a glass substrate having an ITO, a PMPS thin film having a thickness of 50 nm was formed by means of spin coating by using a 0.8 wt % solution of polymethylphenylsilane (PMPS) with a weight-average molecular weight of 70,000 in toluene. Two substrates fabricated as described above were prepared, and one of the substrates was irradiated with an ultraviolet ray in the air (humidity: 50%) for 15 minutes by using a high-pressure mercury lamp (TOSCURE, Toshiba). A coating solution (solids concentration: about 0.75 wt %), which was prepared by adding 2-propanol to a dispersion (BAYTRON P, AI4083, solids concentration: 1.5 wt %) of poly(3,4-oxyethyleneoxythiophene)/polysulfonic acid (PEDOT/PSS) at a ratio of 1:1 as a hydrophilic liquid of a conducting polymer, was dropped onto each of these two substrates, and immediately thereafter, each of these substrates was rotated to form a film having a film thickness of 50 nm by means of spin coating. Subsequently, heat treatment was performed in the air at 120° C. for 60 minutes in order to form substrates D and E which correspond to ultraviolet-irradiated and non-irradiated parts of a patterned substrate, respectively. Using these substrates, N-N′-bis-(1-naphthyl)-N,N′-diphenyl-1,1′-biphenyl 4,4′-diamine (α-NPD) was deposited on the PEDOT/PSS thin film to a thickness of 100 nm by means of vacuum evaporation, and on which an Ag electrode having a film thickness of 40 nm was further deposited to fabricate a device (FIG. 1). The current-voltage (I-V) characteristics (FIG. 2) measured by applying a voltage between the ITO electrode and the Ag electrode of each device shows that a larger amount of current flowed through the ultraviolet-irradiated device E than the ultraviolet-nonirradiated device D. For example, a current running through the ultraviolet-irradiated device E became 4.2 times larger than that of the ultraviolet-nonirradiated device D at 20 V.

### Example 1

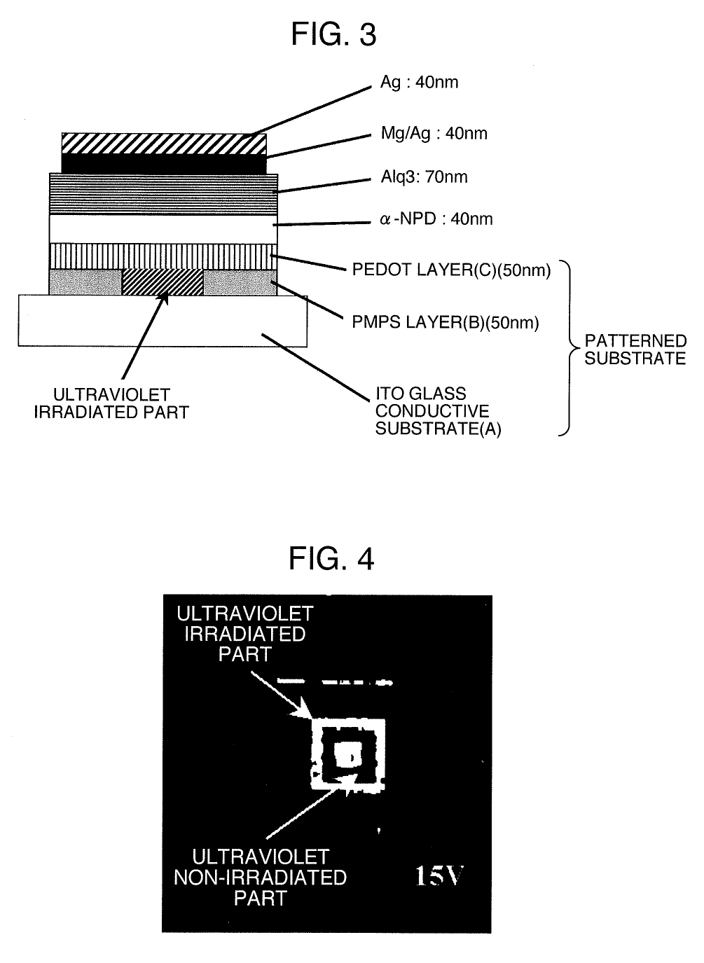

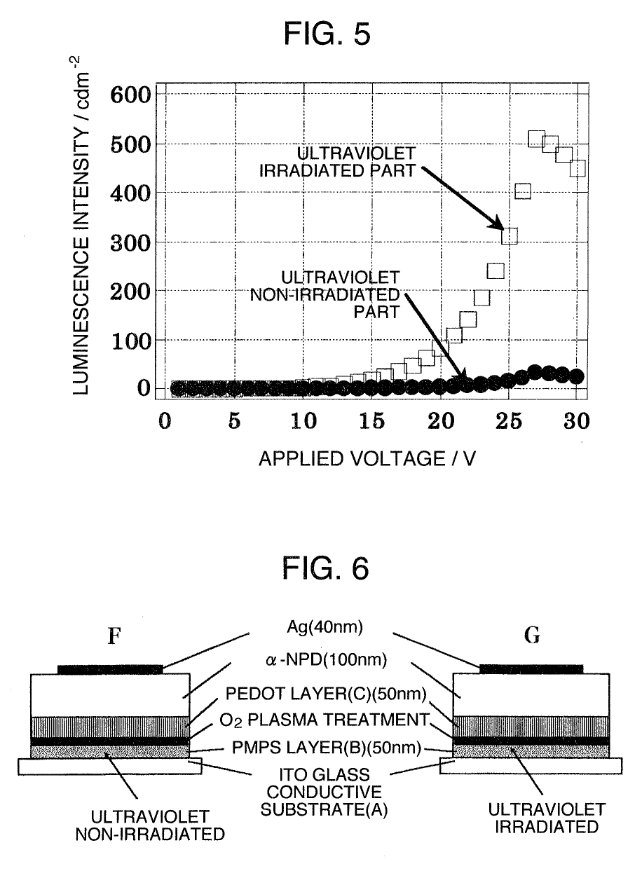

On a glass substrate having an ITO, a PMPS thin film having a thickness of 50 nm was formed by means of spin coating by using a 0.8 wt % solution of PMPS in toluene. This substrate was irradiated with an ultraviolet ray in the air (humidity: 50%) for 15 minutes through a shadow mask. A coating solution, which was prepared by adding 2-propanol to a dispersion of PEDOT/PSS at a ratio of 1:1, was dropped onto the above described substrate, and immediately thereafter, this substrate was rotated to form a film having a film thickness of 50 nm by means of spin coating. Subsequently, heat treatment was performed in the air at 120° C. for 60 minutes to form a patterned substrate. Using this substrate, α-NPD and tris(8-hydroxyquinoline) aluminum (Alq₃) were deposited on the PEDOT/PSS thin film to thicknesses of 40 nm and 70 nm, respectively, by means of vacuum evaporation, on which Mg:Ag having a film thickness of 40 nm was then deposited by means of co-evaporation and an Ag electrode having a film thickness of 40 nm was further deposited in order to fabricate an organic electroluminescence device (see, FIG. 3). A luminescence pattern which was the same as the shadow mask pattern was obtained by applying a voltage of 15 V between the ITO electrode and the Ag electrode of this device (FIG. 4), and consequently it was found that the above described device functioned as a patterned substrate. Measurement of luminescence intensity in regard to the irradiated part and the non-irradiated part shows that a region irradiated with an ultraviolet ray emitted light well (FIG. 5).

### Reference Example 2

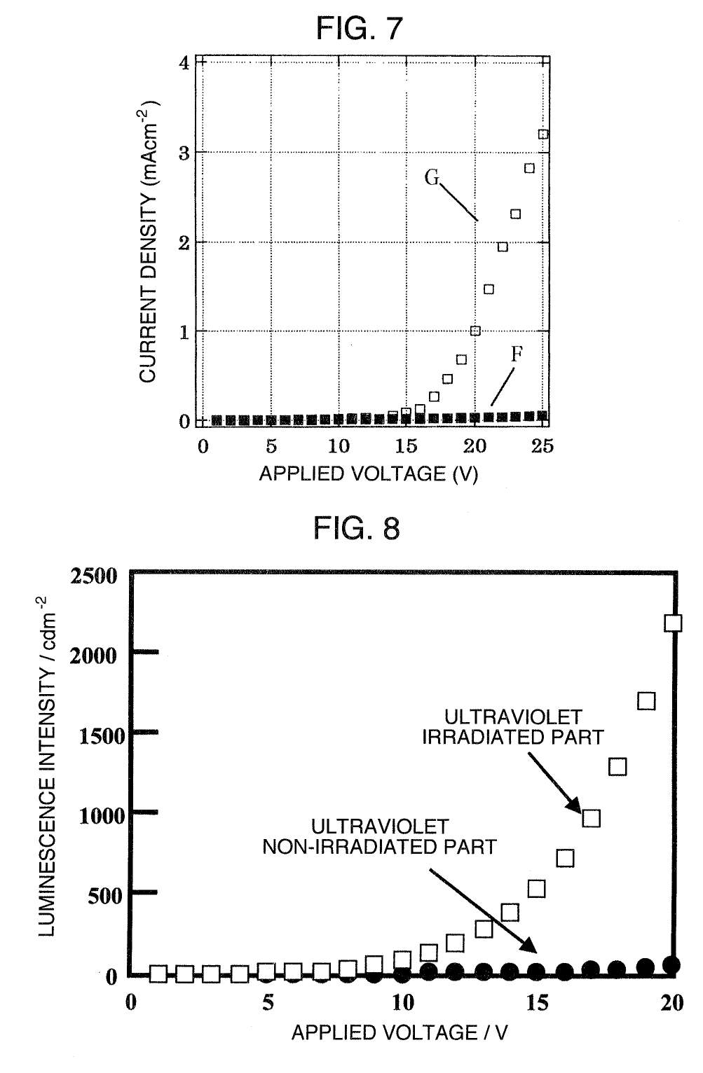

On a glass substrate having ITO, PMPS was formed to a thickness of 50 nm by means of spin coating as described in Reference Example 1. Two substrates fabricated as described above were prepared, and one of the substrates was irradiated with an ultraviolet ray in the air (humidity: 50%) for 15 minutes. These two substrates, one of which was irradiated with an ultraviolet ray and the other of which was not irradiated with an ultraviolet ray, were subjected to an oxygen plasma treatment for making the PMPS surfaces hydrophilic. Subsequently, a coating solution which was prepared by adding 2-propanol to a dispersion of PEDOT/PSS at a ratio of 1:1 as described in Reference Example 1 was dropped onto each of these two substrates, and immediately thereafter, each of these substrates was rotated to form a film having a film thickness of 50 nm by means of spin coating. And then heat treatment was performed in the air at 120° C. for 60 minutes in order to form substrates F and G which respectively correspond to ultraviolet-non-irradiated and ultraviolet-irradiated parts of a patterned substrate (FIG. 6). α-NPD and Ag were further evaporated to fabricate a device. The I-V characteristics (FIG. 7) measured by applying a voltage between the ITO electrode and the Ag electrode of each device shows that a larger amount of current flowed through the ultraviolet-irradiated device G than the ultraviolet-nonirradiated device F. For example, a current flowing through the ultraviolet-irradiated device G became 61 times larger than that of the ultraviolet-nonirradiated device F at 25 V.

### Example 2

A PMPS thin film having a thickness of 50 nm was formed by means of spin coating as described in Example 1. This substrate was irradiated with an ultraviolet ray in the air (humidity: 50%) for 15 minutes through a shadow mask, and then this substrate was subjected to an oxygen plasma treatment to make the organic polysilane surface hydrophilic. A coating solution, which was prepared by adding 2-propanol to a dispersion of PEDOT/PSS at a ratio of 1:1, was dropped onto the above described substrate, and immediately thereafter, this substrate was rotated to form a film having a film thickness of 50 nm by means of spin coating. Subsequently, heat treatment was performed in the air at 120° C. for 60 minutes to fabricate a patterned substrate. Using this substrate, α-NPD and tris(8-hydroxyquinoline) aluminum (Alq₃) were deposited on the PEDOT/PSS thin film to thicknesses of 40 nm and 70 nm, respectively, by means of vacuum evaporation, on which Mg:Ag having a film thickness of 40 nm was then deposited by means of co-evaporation and an Ag electrode having a film thickness of 40 nm was further deposited in order to fabricate an organic electroluminescence device. A luminescence pattern with a high contrast which was the same as the shadow mask pattern was obtained by applying a voltage of 15 V between the ITO electrode and the Ag electrode of this device.

### Example 3

On a glass substrate having ITO, a PMPS thin film having a thickness of 50 nm was formed by means of spin coating as described in Example 1. This substrate was irradiated with an ultraviolet ray in the air (humidity: 50%) for 15 minutes through a shadow mask. A coating solution, which was prepared by adding 2-propanol to a dispersion of PEDOT/PSS at a ratio of 1:1, was dropped onto the above described substrate, and then this substrate was kept for 20 seconds as it is, and thereafter, this substrate was rotated to form a film having a film thickness of 50 nm by means of spin coating. Subsequently, heat treatment was performed in the air at 120° C. for 60 minutes, and then the whole area of the substrate was irradiated with an ultraviolet ray for 1 minute by using a high-pressure mercury lamp as in the case of Reference Example 1 to fabricate a patterned substrate. Using this substrate, α-NPD and tris(8-hydroxyquinoline) aluminum (Alq₃) were deposited on the PEDOT/PSS thin film to thicknesses of 40 nm and 70 nm, respectively, by means of vacuum evaporation, on which Mg:Ag having a film thickness of 40 nm was then deposited by means of co-evaporation and an Ag electrode having a film thickness of 40 nm was further deposited in order to fabricate an organic electroluminescence device (see, FIG. 3). The luminescence intensity-voltage characteristics (FIG. 8) measured by applying a voltage between the ITO electrode and the Ag electrode of this device shows that the ultraviolet-irradiated part emitted light better than the ultraviolet-nonirradiated part. For example, a luminescence intensity of the ultraviolet-irradiated part became 64 times larger than that of the ultraviolet-nonirradiated part at 15 V, so that a luminescence pattern with a high contrast was obtained.

### Example 4

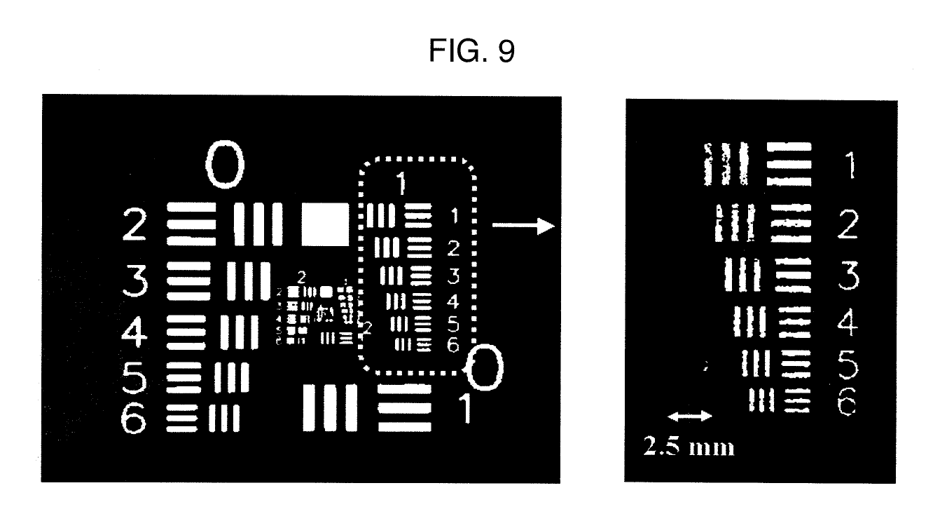

On a glass substrate having ITO, a PMPS thin film having a thickness of 50 nm was formed by means of spin coating as described in Example 1. Using a shadow mask which was prepared from a silica glass substrate having a pattern of 1951USAF test chart thereon, an ultraviolet ray was irradiated for 15 minutes while a space between the shadow mask and the above described substrate was impregnated with a deionized water. A coating solution, which was prepared by adding 2-propanol to a dispersion of PEDOT/PSS at a ratio of 1:1, was dropped onto the above described substrate, and immediately thereafter, this substrate was rotated to form a film having a film thickness of 50 nm by means of spin coating. Subsequently, heat treatment was performed in the air at 120° C. for 60 minutes to fabricate a patterned substrate. Using this substrate, α-NPD and tris(8-hydroxyquinoline) aluminum (Alq₃) were deposited on the PEDOT/PSS thin film to thicknesses of 40 nm and 70 nm, respectively, by means of vacuum evaporation, on which Mg:Ag having a film thickness of 40 nm was then deposited by means of co-evaporation and an Ag electrode having a film thickness of 40 nm was further deposited in order to fabricate an organic electroluminescence device (see, FIG. 3). A luminescence pattern with a high contrast which was the same as the shadow mask pattern was obtained by applying a voltage between the ITO electrode and the Ag electrode of this device (FIG. 9). The pattern resolution at this point was 3.56 lines/mm.

### INDUSTRIAL APPLICABILITY

A patterned substrate according to the present invention can be used for an organic electroluminescence device, an organic transistor device, an organic photo-sensor, an organic solar cell, or an optical-optical conversion device etc.

1. A method for producing a patterned substrate having a conductor pattern, comprising:
forming layer (B) comprising an organic polysilane on conductive substrate (A);
irradiating a certain region of the layer (B) with a radiation to oxidize the organic polysilane constituting the layer (B) in the certain region; and then
applying a solution containing a conducting polymer, water, and/or a hydrophilic solvent at least on the certain region of the layer (B) to form layer (C) comprising the conducting polymer, while impregnating the layer (B) in the certain region with the conducting polymer to electrically connect the layer (C) and the substrate (A) to fabricate the conductor pattern.

2. The method according to claim 1, wherein the irradiation is performed through a shadow mask pattern.

3. The method according to claim 1, wherein the irradiation is performed in an atmosphere having a humidity of 30% or more.

4. The method according to claim 1, characterized in that a surface of the layer (B) excluding the irradiated region is oxidized after the organic polysilane constituting the layer (B) in the irradiated region is oxidized.

5. The method according to claim 4, wherein the surface of the irradiated region of the layer (B) and the solution containing the conducting polymer, water, and/or a hydrophilic solvent are allowed to contact with each other and then are kept as they are for 15 seconds or more, before applying the solution containing the conducting polymer, water, and/or the hydrophilic solvent on said surface.

6. The method according to claim 1, wherein after impregnating the layer (B) in the irradiated region with the conducting polymer, the layer (B) is irradiated with a radiation to oxidize the organic polysilane constituting the layer (B) excluding the irradiated region.
